(19) United States
(12) Patent Application Publication
(10) Pub. No.: US 2023/0039670 A1
(43) Pub. Date: Feb. 9, 2023

(54) MIXED METAL BASEPLATES FOR IMPROVED THERMAL EXPANSION MATCHING WITH THERMAL OXIDE SPRAYCOAT

(71) Applicant: LAM RESEARCH CORPORATION, Fremont, CA (US)

(72) Inventors: Eric SAMULON, Oakland, CA (US); Darrell EHRLICH, San Jose, CA (US)

(21) Appl. No.: 17/790,009

(22) PCT Filed: Jan. 8, 2021
(86) PCT No.: PCT/US2021/012593

§ 371 Date: Jun. 29, 2022

Related U.S. Application Data
(60) Provisional application No. 62/960,417, filed on Jan. 13, 2020.

(51) Int. Cl. H01L 21/687; C23C 16/458

(52) U.S. Cl. CPC H01L 21/68757; C23C 16/4581

(57) ABSTRACT

A baseplate of a substrate support assembly for supporting a semiconductor substrate in a processing chamber comprises a first component made of a first material including a metal and a nonmetal. The first material has a first coefficient of thermal expansion. A layer coating the first component is made of a second material. The second material has a second coefficient of thermal expansion. The first and second coefficients of thermal expansion are different.

### CROSS-REFERENCE TO RELATED APPLICATIONS

This application claims the benefit of U.S. Provisional Application No. 62/960,417, filed on Jan. 13, 2020. The entire disclosure of the application referenced above is incorporated herein by reference.

### FIELD

The present disclosure relates generally to substrate processing systems and more particularly to using mixed metal baseplates in processing chambers for improving thermal expansion matching with spray coat applied on the baseplates.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform deposition, etching, and other treatments of substrates such as semiconductor wafers. Examples of processes that may be performed on a substrate include, but are not limited to, a plasma enhanced chemical vapor deposition (PECVD) process, a chemically enhanced plasma vapor deposition (CEPVD) process, and a sputtering physical vapor deposition (PVD) process. Additional examples of processes that may be performed on a substrate include, but are not limited to, etching (e.g., chemical etching, plasma etching, reactive ion etching, etc.) and cleaning processes.

During processing, a substrate is arranged on a substrate support such as a pedestal, an electrostatic chuck (ESC), and so on in a processing chamber of the substrate processing system. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. A computer-controlled robot typically transfers substrates from one processing chamber to another in a sequence in which the substrates are to be processed.

### SUMMARY

A baseplate of a substrate support assembly for supporting a semiconductor substrate in a processing chamber comprises a first component made of a first material including a metal and a nonmetal. The first material has a first coefficient of thermal expansion. A layer coating the first component is made of a second material. The second material has a second coefficient of thermal expansion. The first and second coefficients of thermal expansion are different.

In another feature, the first and second coefficients of thermal expansion are within a predetermined range.

In another feature, the first coefficient of thermal expansion is greater than the second coefficient of thermal expansion.

In another feature, the first coefficient of thermal expansion is less than a coefficient of thermal expansion of the metal.

In other features, the predetermined range is between first and second values. The second value is greater than the first value. The first coefficient of thermal expansion is closer to the second value than the first value. The second coefficient of thermal expansion is closer to the first value than the second value.

In another feature, the predetermined range is between 6 and 12.

In another feature, a thickness of the layer of the second material is between 30 μm and 2 mm.

In other features, the first coefficient of thermal expansion is about 11. The second coefficient of thermal expansion is about 8.

In other features, the metal is aluminum. The nonmetal is silicon carbide.

In another feature, the second material is a ceramic material.

In another feature, the second material is alumina or yittria.

In other features, the baseplate further comprises a second layer made of a third material disposed on the layer coating the first component, and a third component made of the second material disposed on the second layer.

In another feature, the second layer bonds the third component to the first component.

In other features, the second layer conducts heat between the third component and the first component and absorbs shearing stress over a predetermined temperature range for a predetermined time period.

In still other features, a method for manufacturing a baseplate of a substrate support assembly for supporting a semiconductor substrate in a processing chamber comprises manufacturing a first component of the baseplate using a first material including a metal and a nonmetal. The first material has a first coefficient of thermal expansion. The method comprises coating the first component of the baseplate with a layer of a second material having a second coefficient of thermal expansion. The first and second coefficients of thermal expansion are different.

In another feature, the first and second coefficients of thermal expansion are within a predetermined range.

In another feature, the first coefficient of thermal expansion is greater than the second coefficient of thermal expansion.

In another feature, the first coefficient of thermal expansion is less than a coefficient of thermal expansion of the metal.

In other features, the predetermined range is between first and second values. The second value is greater than the first value. The first coefficient of thermal expansion is closer to the second value than the first value. The second coefficient of thermal expansion is closer to the first value than the second value.

In another feature, the predetermined range is between 6 and 12.

In another feature, a thickness of the layer of the second material is between 30 μm and 2 mm.

In other features, the first coefficient of thermal expansion is about 11. The second coefficient of thermal expansion is about 8.

In another feature, the method further comprises selecting aluminum as the metal, and selecting silicon carbide as the nonmetal.

In another feature, the method further comprises selecting a ceramic material as the second material.

In another feature, the method further comprises selecting alumina or yittria as the second material.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows a first example of a substrate processing system comprising a processing chamber;

FIG. 2 shows a second example of a substrate processing system comprising a processing chamber;

FIG. 3 shows a third example of a substrate processing system comprising a processing chamber;

FIGS. 4 and 5 schematically show an example of a baseplate according to the present disclosure that can be used in a processing chamber of a substrate processing system;

FIG. 6 shows a method of manufacturing the baseplate shown in FIGS. 4 and 5 for a substrate support assembly of a substrate processing system according to the present disclosure; and

FIG. 7 shows a method for manufacturing a substrate of the baseplate shown in FIGS. 4 and 5 according to the present disclosure.

In the drawings, reference numbers may be reused to identify similar and/or identical elements.

### DETAILED DESCRIPTION

A baseplate is a basic component of a processing chamber on which a wafer is arranged during processing. The baseplate is typically made of a metal substrate with a spray coat of an oxide material covering the outside of the metal substrate. The spray coat is used to protect the baseplate (i.e., the metal substrate) from extreme environs of the processing chamber (e.g., to protect the baseplate from plasma erosion and arcing).

Depending on the process, the baseplate can be utilized over a wide temperature range of greater than about 100 degrees Celsius, for example. Managing the stress on the spray coat over the entire operating regime, to ensure proper adhesion of the spray coat to the metal substrate and to ensure reduction of cracking of the spray coat, can be difficult due to a mismatch in the thermal expansion of the metal substrate compared to the spray coat. According to the present disclosure, by utilizing a mixed metal substrate with thermal expansion better matching the spray coat, the stress on the spray coat can be relatively relieved over the full operational regime.

Baseplates are typically made of aluminum with a spray coat of aluminum oxide covering layer. The coefficient of thermal expansion of aluminum is greater than 20 μm/° Cm. This is significantly greater than the coefficient of thermal expansion of the aluminum oxide, which is near 8 μm/° Cm. As the oxide layer is applied at high temperatures, the coat experiences large tensile stresses at cryogenic temperature where the aluminum substrate shrinks much more than the oxide spray coat.

The present disclosure provides baseplates comprising mixed metal substrates to better match the thermal expansion properties of the underlying substrate to the thermal expansion properties of the spray coat applied over the substrate. Specifically, according to the present disclosure, the aluminum metal substrate in the baseplate is replaced with a mixed metal substrate having a coefficient of thermal expansion that is better matched with the spray coat (e.g., the aluminum oxide layer). For example, materials called metal matrix composites (explained below) are used as baseplate substrates on which a ceramic material is spray coated. By better matching the coefficient of thermal expansion between the mixed metal substrate and the spray coat, the stress on the spray coat can be maintained close to a zero stress condition for most or all operating temperatures. This mitigates the need to change the dimensional design of the baseplate to minimize stress on the spray coat.

The teachings of the present disclosure are not limited only to the baseplates. Rather, the teachings can be extended and applied to various other components of processing chambers that typically include a metal substrate covered with a spray coat of an oxide layer and that experience stresses due to the extreme environs of the processing chambers. These components can also be manufactured using the mixed metal substrates that are coated with a ceramic layer such that there is improved matching of thermal expansion between the substrate and the ceramic layer, which reduces the stresses on these components. Non-limiting examples such components include inner walls of the processing chambers, various annular ring shaped components used in the processing chambers, showerheads, etc.

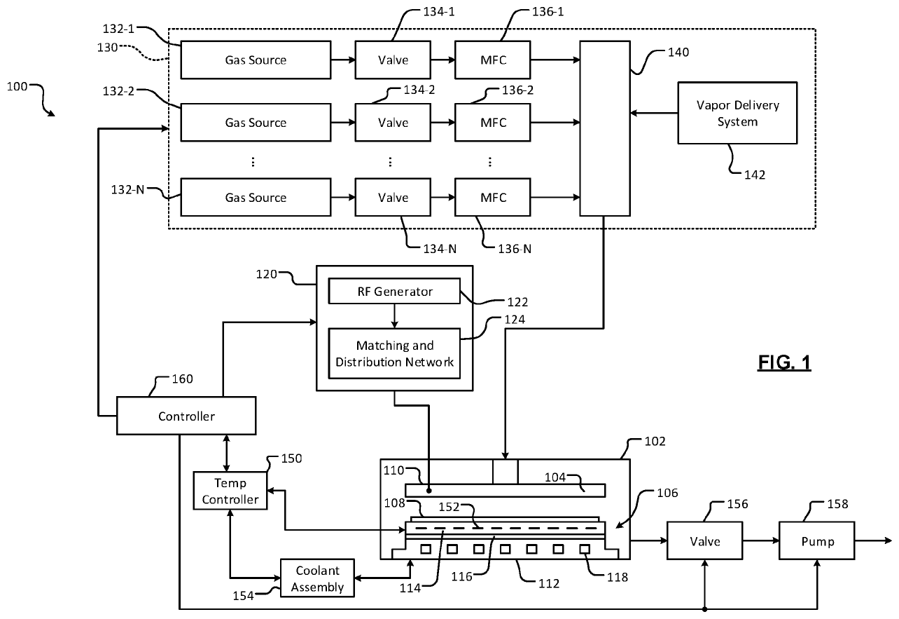

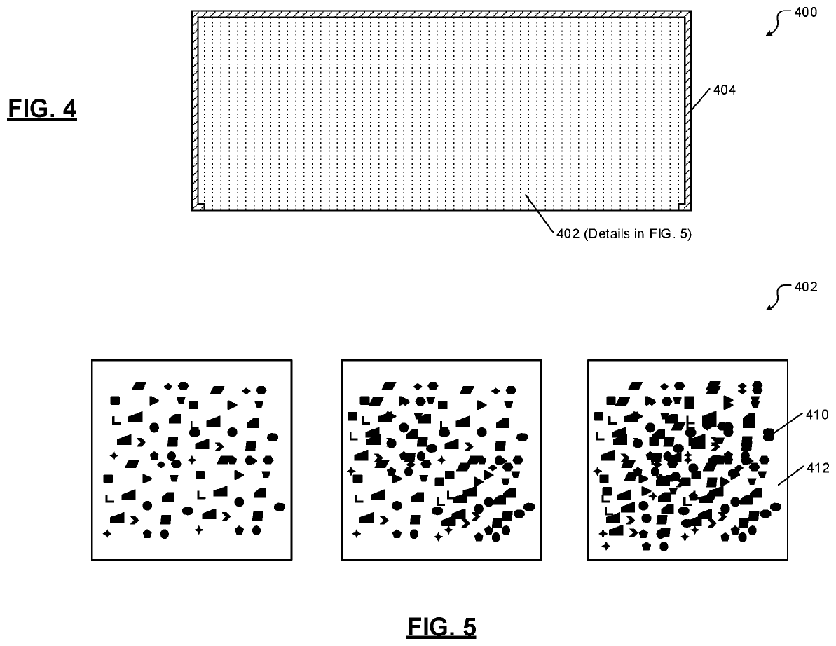

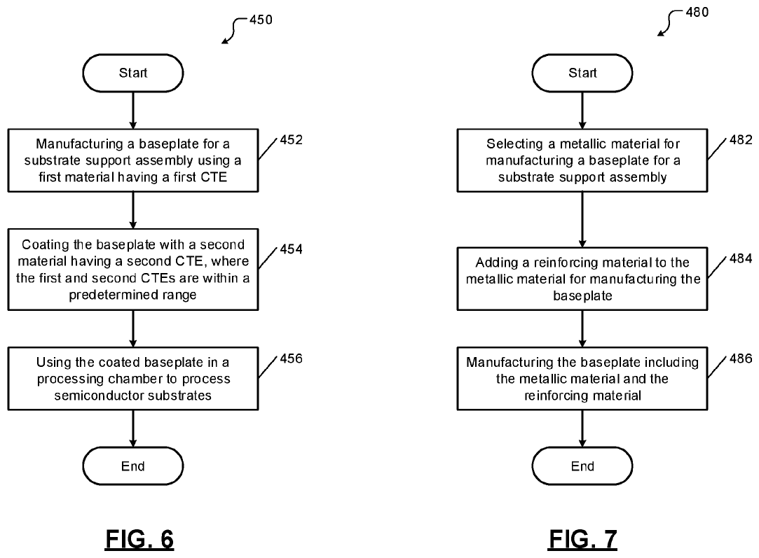

The present disclosure is organized as follows. Initially, to comprehend the harsh environs in the processing chambers and the diverse components to which the teachings of the present disclosure can be applied, examples of different processing chambers are shown and described with reference to FIGS. 1-3. Subsequently, the metal matrix composite (MMC) materials are explained in detail. Thereafter, example designs of baseplates according to the present disclosure are shown and described with reference to FIGS. 4-5. Subsequently, example methods of manufacturing the baseplates according to the present disclosure are shown and described with reference to FIGS. 6-7.

FIG. 1 shows an example of a substrate processing system 100 comprising a processing chamber 102. While the example is described in the context of plasma enhanced chemical vapor deposition (PECVD), the teachings of the present disclosure can be applied to other types of substrate processing such as atomic layer deposition (ALD), plasma enhanced ALD (PEALD), CVD, or also other processing including etching processes. The system 100 comprises the processing chamber 102 that encloses other components of the system 100 and contains an RF plasma (if used). The processing chamber 102 comprises an upper electrode 104 and an electrostatic chuck (ESC) 106 or other substrate support. During operation, a substrate 108 is arranged on the ESC 106.

For example, the upper electrode 104 may include a gas distribution device 110 such as a showerhead that introduces and distributes process gases. The gas distribution device 110 may include a stem portion including one end connected to a top surface of the processing chamber 102. A base portion of the showerhead is generally cylindrical and extends radially outwardly from an opposite end of the stem portion at a location that is spaced from the top surface of the processing chamber 102. A substrate-facing surface or faceplate of the base portion of the showerhead includes a plurality of holes through which vaporized precursor, process gas, or purge gas flows. Alternately, the upper electrode 104 may include a conducting plate, and the process gases may be introduced in another manner.

The ESC 106 comprises a baseplate 112 that acts as a lower electrode. The baseplate 112 may include one or more channels 118 for flowing coolant through the baseplate 112. The baseplate 112 supports a ceramic plate 114 on which the substrate 108 is arranged during processing. A bonding layer 116 is disposed between the baseplate 112 and the ceramic plate 114. In some applications, the ceramic plate 114 may include one or more heaters (e.g., multi-zone heaters, not shown).

If plasma is used, an RF generating system 120 generates and outputs an RF voltage to one of the upper electrode 104 and the lower electrode (e.g., the baseplate 112 of the ESC 106). The other one of the upper electrode 104 and the baseplate 112 may be DC grounded, AC grounded, or floating. For example only, the RF generating system 120 may include an RF generator 122 that generates RF power that is fed by a matching and distribution network 124 to the upper electrode 104 or the baseplate 112. In other examples, the plasma may be generated inductively or remotely.

A gas delivery system 130 includes one or more gas sources 132-1, 132-2, . . . , and 132-N(collectively gas sources 132), where N is an integer greater than zero. The gas sources 132 are connected by valves 134-1, 134-2, . . . , and 134-N(collectively valves 134) and mass flow controllers 136-1, 136-2, . . . , and 136-N(collectively mass flow controllers 136) to a manifold 140. A vapor delivery system 142 supplies vaporized precursor to the manifold 140 or another manifold (not shown) that is connected to the processing chamber 102. An output of the manifold 140 is fed to the processing chamber 102.

A temperature controller 150 may communicate with a coolant assembly 154 to control coolant flow through the channels 118. For example, the coolant assembly 154 may include a coolant pump, a reservoir, and one or more temperature sensors (not shown). The temperature controller 150 operates the coolant assembly 154 to selectively flow the coolant through the channels 118 to cool the ESC 106. In some applications, when the ceramic plate 114 includes the heater 152, the temperature controller 150 may be connected to a plurality of thermal control elements (TCEs) 152 arranged in the ceramic plate 114. The temperature controller 150 may be used to control the plurality of TCEs 152 to control a temperature of the ESC 106 and the substrate 108. A valve 156 and pump 158 may be used to evacuate reactants from the processing chamber 102. A system controller 160 controls the components of the system 100.

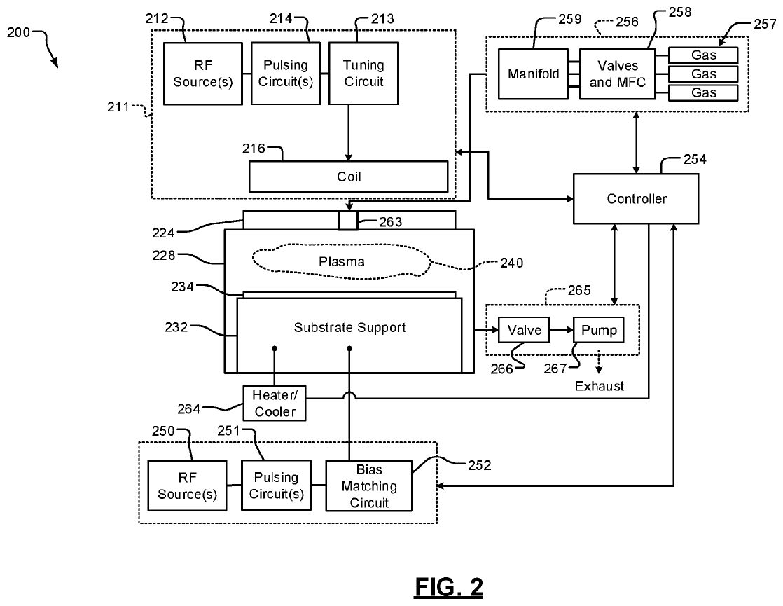

FIG. 2 shows another example of a substrate processing system 200. The substrate processing system 200 includes a coil driving circuit 211. In some examples, the coil driving circuit 211 includes an RF source 212, a pulsing circuit 214, and a tuning circuit (i.e., matching circuit) 213. The pulsing circuit 214 controls a transformer coupled plasma (TCP) envelope of an RF signal generated by the RF source 212 and varies a duty cycle of TCP envelope between 1% and 99% during operation. As can be appreciated, the pulsing circuit 214 and the RF source 212 can be combined or separate in some implementations.

The tuning circuit 213 may be directly connected to an inductive coil 216. While the substrate processing system 210 uses a single coil, some substrate processing systems may use a plurality of coils (e.g., inner and outer coils). The tuning circuit 213 tunes an output of the RF source 212 to a desired frequency and/or a desired phase, and matches an impedance of the coil 216.

A dielectric window 224 is arranged along a top side of a processing chamber 228. The processing chamber 228 comprises a substrate support (or pedestal) 232 to support a substrate 234. The substrate support 232 may include an electrostatic chuck (ESC), or a mechanical chuck or other type of chuck. Process gas is supplied to the processing chamber 228 and plasma 240 is generated inside of the processing chamber 228. The plasma 240 etches an exposed surface of the substrate 234. An RF source 250, a pulsing circuit 251, and a bias matching circuit 252 may be used to bias the substrate support 232 during operation to control ion energy.

A gas delivery system 256 may be used to supply a process gas mixture to the processing chamber 228. The gas delivery system 256 may include process and inert gas sources 257, a gas metering system 258 such as valves and mass flow controllers, and a manifold 259. A gas injector 263 may be arranged at a center of the dielectric window 224 and is used to inject gas mixtures from the gas delivery system 256 into the processing chamber 228. Additionally or alternatively, the gas mixtures may be injected from the side of the processing chamber 228.

A heater/cooler 264 may be used to heat/cool the substrate support 232 to a predetermined temperature. An exhaust system 265 includes a valve 266 and pump 267 to control pressure in the processing chamber and/or to remove reactants from the processing chamber 228 by purging or evacuation.

A controller 254 may be used to control the etching process. The controller 254 monitors system parameters and controls delivery of the gas mixture; striking, maintaining, and extinguishing the plasma; removal of reactants; supply of cooling gas; and so on. Additionally, as described below, the controller 254 may control various aspects of the coil driving circuit 210, the RF source 250, and the bias matching circuit 252, and so on.

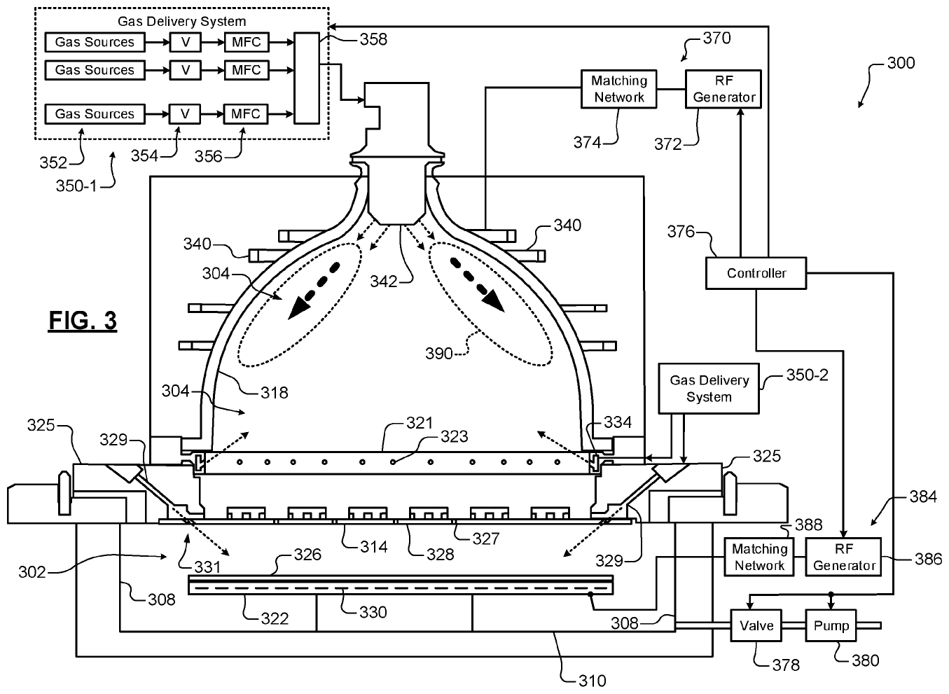

FIG. 3 shows a processing chamber 300 for etching a layer of a substrate. The processing chamber 300 includes a lower chamber region 302 and an upper chamber region 304. The lower chamber region 302 is defined by chamber sidewall surfaces 308, a chamber bottom surface 310, and a lower surface of a gas distribution device 314. The upper chamber region 304 is defined by an upper surface of the gas distribution device 314 and an inner surface of a dome 318.

In some examples, the dome 318 rests on a first annular support 321. In some examples, the first annular support 321 includes one or more spaced holes 323 for delivering process gas to the upper chamber region 304. In some examples, the process gas is delivered by the one or more spaced holes 323 in an upward direction at an acute angle relative to a plane including the gas distribution device 314, although other angles/directions may be used. In some examples, a gas flow channel 334 in the first annular support 321 supplies gas to the one or more spaced holes 323.

The first annular support 321 may rest on a second annular support 325 that defines one or more spaced holes 327 for delivering process gas from a gas flow channel 329 to the lower chamber region 302. In some examples, holes 331 in the gas distribution device 314 align with the holes 327. In other examples, the gas distribution device 314 has a smaller diameter, and the holes 331 are not needed. In some examples, the process gas is delivered by the one or more spaced holes 327 in a downward direction towards a substrate 326 at an acute angle relative to the plane including the gas distribution device 314, although other angles/directions may be used. In other examples, the upper chamber region 304 is cylindrical with a flat top surface and one or more flat inductive coils may be used. In some examples, a single chamber may be used with a spacer located between a showerhead and the substrate support.

A substrate support 322 is arranged in the lower chamber region 304. In some examples, the substrate support 322 includes an electrostatic chuck (ESC), although other types of substrate supports can be used. The substrate 326 is arranged on an upper surface of the substrate support 322 during etching. In some examples, a temperature of the substrate 326 may be controlled by a heater plate 330, an optional cooling plate with fluid channels, and one or more sensors (not shown), although any other suitable substrate support temperature control system may be used.

In some examples, the gas distribution device 314 includes a showerhead (for example, a plate 328 having a plurality of spaced holes 327). The plurality of spaced holes 327 extend from the upper surface of the plate 328 to the lower surface of the plate 328. In some examples, the spaced holes 327 have a diameter in a range from 0.4″ to 0.75″ and the showerhead is made of a conducting material such as aluminum or a non-conductive material such as ceramic with an embedded electrode made of a conducting material.

One or more inductive coils 340 are arranged around an outer portion of the dome 318. When energized, the one or more inductive coils 340 create an electromagnetic field inside of the dome 318. In some examples, an upper coil and a lower coil are used. A gas injector 342 injects one or more gas mixtures from a gas delivery system 350-1. In some examples, the gas delivery system 350-1 includes one or more gas sources 352, one or more valves 354, one or more mass flow controllers (MFCs) 356, and a mixing manifold 158, although other types of gas delivery systems may be used. A gas splitter (not shown) may be used to vary flow rates of a gas mixture. Another gas delivery system 350-2 may be used to supply an etch gas or an etch gas mixture to the gas flow channels 329 and/or 334 (in addition to or instead of etch gas from the gas injector 342).

In some examples, the gas injector 342 includes a center injection location that directs gas in a downward direction and one or more side injection locations that inject gas at an angle with respect to the downward direction. In some examples, the gas delivery system 350-1 delivers a first portion of the gas mixture at a first flow rate to the center injection location and a second portion of the gas mixture at a second flow rate to the side injection location(s) of the gas injector 342. In other examples, different gas mixtures are delivered by the gas injector 342. In some examples, the gas delivery system 350-1 delivers tuning gas to the gas flow channels 329 and 334 and/or to other locations in the processing chamber as will be described below.

A plasma generator 370 may be used to generate RF power that is output to the one or more inductive coils 340. Plasma 390 is generated in the upper chamber region 304. In some examples, the plasma generator 370 includes an RF generator 372 and a matching network 374. The matching network 374 matches an impedance of the RF generator 372 to the impedance of the one or more inductive coils 340. In some examples, the gas distribution device 314 is connected to a reference potential such as ground. A valve 378 and a pump 380 may be used to control pressure inside of the lower and upper chamber regions 302, 304 and to evacuate reactants.

A controller 376 communicates with the gas delivery systems 350-1 and 350-2, the valve 378, the pump 380, and the plasma generator 370 to control flow of process gas, purge gas, RF plasma and chamber pressure. In some examples, plasma is sustained inside the dome 318 by the one or more inductive coils 340. One or more gas mixtures are introduced from a top portion of the chamber using the gas injector 342 (and/or holes 323), and plasma is confined within the dome 318 using the gas distribution device 314.

Confining the plasma in the dome 318 allows volume recombination of plasma species and effusing desired etchant species through the gas distribution device 314. In some examples, there is no RF bias applied to the substrate 326. As a result, there is no active sheath on the substrate 326 and ions are not hitting the substrate with any finite energy. Some amount of ions will diffuse out of the plasma region through the gas distribution device 314. However, the amount of plasma that diffuses is an order of magnitude lower than the plasma located inside the dome 318. Most ions in the plasma are lost by volume recombination at high pressures. Surface recombination loss at the upper surface of the gas distribution device 314 also lowers ion density below the gas distribution device 314.

In other examples, an RF bias generator 384 is provided and includes an RF generator 386 and a matching network 388. The RF bias can be used to create plasma between the gas distribution device 314 and the substrate support or to create a self-bias on the substrate 326 to attract ions. The controller 376 may be used to control the RF bias.

The metal matrix composite (MMC) materials are now explained in detail. A metal matrix composite (MMC) is a composite material with at least two constituents, one being a metal while the other may be a different metal or another material such as a ceramic or an organic compound. When at least three materials are used, the MMC is called a hybrid composite.

MMCs are made by dispersing a reinforcing material into a metal matrix. The reinforcement surface can be coated to prevent a chemical reaction with the matrix. For example, carbon fibers are used in aluminum matrix to synthesize composites exhibiting low density and high strength. However, carbon reacts with aluminum to generate a brittle and water-soluble compound on the surface of the fiber. To prevent the reaction, the carbon fibers are coated with nickel or titanium boride.

The matrix is a monolithic material into which the reinforcement material is embedded, and is continuous (i.e., a path exists through the matrix to any point in the material, unlike when two materials are sandwiched together). In structural applications, the matrix is usually a lighter metal such as aluminum, magnesium, or titanium, and provides support for the reinforcement. In high-temperature applications, cobalt and cobalt-nickel alloy matrices may be used.

The reinforcement does not always serve a purely structural task (e.g., reinforcing the compound) but is also used to change physical properties such as wear resistance, friction coefficient, and thermal conductivity. The reinforcement can be continuous or discontinuous. Discontinuous MMCs can be isotropic and can be worked with using standard metalworking techniques such as extrusion, forging, or rolling. In addition, they may be machined using conventional techniques but may need further tooling using techniques such as polycrystalline diamond tooling (PCD).

Continuous reinforcement uses monofilament wires or fibers such as carbon fiber or silicon carbide. Because the fibers are embedded into the matrix in a certain direction, the result is an anisotropic structure in which the alignment of the material affects its strength. Discontinuous reinforcement use short fibers or particles. Examples of such reinforcing materials include alumina and silicon carbide.

MMC manufacturing can be generally of three types: solid, liquid, and vapor. MMCs are fabricated at elevated temperatures for diffusion bonding of the fiber/matrix interface. Later, when they are cooled to ambient temperature, residual stresses are generated in the composite due to the mismatch between the coefficients of the metal matrix and fiber. The residual stresses during manufacturing significantly influence the mechanical behavior of the MMCs in all loading conditions. In some cases, thermal residual stresses are high enough to initiate plastic deformation within the matrix during the manufacturing process.

Solid state manufacturing methods include powder blending and consolidation (powder metallurgy). In this method, powdered metal and discontinuous reinforcement are mixed and then bonded through a process of compaction, degassing, and thermo-mechanical treatment, possibly via hot isostatic pressing (HIP) or extrusion. Other solid state manufacturing methods include foil diffusion bonding. In this method, layers of metal foil are sandwiched with long fibers and then pressed through to form a matrix.

Liquid state manufacturing methods include electroplating and electroforming. In this method, a solution containing metal ions loaded with reinforcing particles is co-deposited forming a composite material. Other liquid state manufacturing methods include stir casting. In this method discontinuous reinforcement is stirred into molten metal, which is allowed to solidify. In pressure infiltration method, molten metal is infiltrated into the reinforcement using gas pressure, for example. In squeeze casting method, molten metal is injected into a form with fibers pre-placed inside it. In spray deposition method, molten metal is sprayed onto a continuous fiber substrate. In reactive processing method, a chemical reaction occurs with one of the reactants forming the matrix and the other the reinforcement.

Still other methods include a semi-solid powder processing method, where powder mixture is heated up to semi-solid state and pressure is applied to form the composites. In physical vapor deposition method, the fiber is passed through a thick cloud of vaporized metal, coating it. In in-situ fabrication method, the fiber is passed through a thick cloud of vaporized metal, coating it.

MMCs are more expensive than the conventional materials they replace. As a result, they are used where improved properties and performance can justify the added cost. Examples of these applications include aircraft components, space systems, and high-end or boutique sports equipment.

In comparison with conventional polymer matrix composites, MMCs are resistant to fire, can operate in wider range of temperatures, do not absorb moisture, have better electrical and thermal conductivity, are resistant to radiation damage, and do not exhibit outgassing. On the other hand, MMCs tend to be more expensive, the fiber-reinforced materials may be difficult to fabricate, and the available experience in use is limited.

FIGS. 4 and 5 schematically show an example of a baseplate 400 according to the present disclosure. Elements of the baseplate 400 such as cooling channels, heaters, electrodes, and so on are omitted to emphasize the details regarding the composition of the baseplate 400. In FIG. 4, the baseplate 400 comprises a mixed metal substrate 402 (show in detail in FIG. 5) that is covered with a ceramic coating 404. For example, the substrate 402 can include an MMC material made from a metal such as aluminum and a reinforcing material such as silicon carbide. For example, the ceramic coating 404 can include aluminum oxide (e.g., alumina or Al₂O₃) spray coated on the substrate 402.

FIG. 5 shows examples of the composition of the substrate 402. For example, the substrate 402 can include different densities of the reinforcing material in the metal. For example, the density of the reinforcing material 410 such as silicon carbide combined with the metal 412 such as aluminum can vary as shown in the three examples from left to right. As the density of the reinforcing material 410 increases in the examples shown from left to right, the coefficient of thermal expansion (CTE) of the composite material (i.e., the metal 412 and the reinforcing material 410) of the substrate 402 decreases. For example, when the metal 412 is aluminum and the reinforcing material 410 is silicon carbide, the CTEs of the composite materials shown in the left, center, and right boxes may be respectively 14, 12, and 11. Accordingly, in the example shown, it can be said that the CTE of the composite material decreases in inverse proportion to the density of the reinforcing material 410 in the metal 412.

Notably, in the example shown, the CTEs of the composite materials are significantly less than the CTE of aluminum, which is about 22, and is closer to the CTE of alumina, which is about 8. Preferably, a composite material with CTE in the range of 6-12 can be used as the substrate 402 for the baseplate 400 along with a layer of alumina spray coated on the substrate 402. Thus, for example, the composite material shown in the right box in FIG. 5, where the density of the reinforcing material (e.g., silicon carbide) 410 in the metal (e.g., aluminum) 412 yields a composite material with a CTE of about 11, is suitable for forming the substrate 402 of the baseplate 400. The substrate 402 thus formed can then be spray coated with a layer of alumina with a CTE of about 8. This combination of using the substrate 402 composed of the composite material formed of aluminum and silicon carbide with a CTE of about 11 and using a spray coat of alumina with a CTE of about 8 minimizes the stresses on the baseplate 400 in the processing chambers. Consequently, the combination of aluminum and silicon carbide spray coated with alumina prevents cracking of the layer of alumina (i.e., the ceramic material 404) coated on the substrate 402 due to better matching of the CTEs of the substrate 402 (e.g., aluminum and silicon carbide) and the ceramic material 404 (e.g., alumina).

FIG. 6 shows a method 450 of manufacturing a baseplate (e.g., the baseplate 400 shown in FIGS. 4 and 5) for a substrate support assembly according to the present disclosure. At 452, the method 450 includes manufacturing the baseplate using a first material (e.g., the substrate 402 of the baseplate 400 shown in FIGS. 4 and 5) having a first CTE. At 454, the method 450 includes coating the first material (e.g., the substrate 402 of the baseplate 400 shown in FIGS. 4 and 5) with a second material (e.g., the ceramic coating 404 of the baseplate 400 shown in FIGS. 4 and 5) having a second CTE, where the first and second CTEs are within a predetermined range.

For example, the predetermined range (e.g., 6-12) has a first value (e.g., 6) and a second value (e.g., 12) that is greater than the first value. The first CTE has a value (e.g., 11) within the predetermined range (e.g., 6-12). The second CTE has a value (e.g., 8) within the predetermined range (e.g., 6-12). For example, the second CTE is less than the first CTE. For example, the first CTE (e.g., 11) is closer to the second value (e.g., 12) of the predetermined range (e.g., 6-12) than to the first value (e.g., 8) of the predetermined range (e.g., 6-12). For example, the second CTE (e.g., 8) is closer to the first value (e.g., 6) of the predetermined range (e.g., 6-12) than to the second value (e.g., 12) of the predetermined range (e.g., 6-12). At 454, the method 450 includes using the coated baseplate (e.g., the baseplate 400 shown in FIGS. 4 and 5) in a processing chamber.

Of course, any other materials with CTEs in the range 6-12 may be used to manufacture the baseplates. That is, any materials with CTEs in the range 6-12 can be used as the substrate and the coating material of the baseplate. Further, in some implementations, so long as the CTEs are in the range of 6-12, the second CTE of the coating material can also be greater than the first CTE of the substrate material.

FIG. 7 shows a method 480 for manufacturing a substrate of a baseplate (e.g., the substrate 402 of the baseplate 400 shown in FIGS. 4 and 5, which is the first material described in FIG. 6) according to the present disclosure. At 482, the method 480 includes selecting a metal for manufacturing the substrate (i.e., the first material). For example, the method 480 includes selecting element 412 shown in FIG. 5. For example, the method 480 includes selecting aluminum as element 412 shown in FIG. 5. At 484, method 480 includes adding a reinforcing material (e.g., element 410 shown in FIG. 5) to the metal. For example, the method 480 includes selecting silicon carbide as element 410 shown in FIG. 5. At 486, the method 480 includes manufacturing the substrate for the baseplate using the metal and the reinforcing material.

It should be noted that manufacturing a baseplate including, for example, a combination of aluminum and silicon carbide and with a coating of alumina is not merely a design choice or a result of routine experimentation. Rather, it is a product of thorough and extensive investigations into various materials, their properties, and their behaviors in varying combinations and under widely differing thermal, chemical, and electrical operating conditions occurring in different substrate processing systems. The present disclosure fulfills the long felt need in the industry, which is how to minimize the stress on and prevent the cracking of the coating on the baseplates. The present disclosure provides the unexpected result of minimizing the stress on and preventing the cracking of the coating on the baseplates by keeping the CTEs of both the substrate and the coating of the baseplate within a narrow range as described above.

The baseplate of the MMC material can be manufactured using various processes including casting, machining, 3D printing, and so on. Further, in some examples, the coating material on the MMC material can also include other materials such as yittria (i.e., yittrium oxide or Y₂O₃), which can be used in manufacturing some of the components of the processing chambers, for example.

One of the advantages of using the MMC material for the baseplate is the ability to spray the baseplate with a thicker spray coat than when the baseplate is made of a metal such as aluminum. For example, the thickness of the coating material can be about 30 μm to about 2 mm. The limitation on spray coat thickness on aluminum baseplates is the stress built up in the coating film (which induces spray coat cracking). The stress is related (among other factors) to the lattice mismatch and adhesion properties between the substrate (metal) and the film of the coating. By changing the substrate of the baseplate from metal to MMC, the stress on the coating can be reduced to enable thicker films.

A thicker film coating can have multiple uses. For example, a thicker film can be simply used for higher voltage standoff to enable larger RF voltages on the ESC. Further, in a process being performed in a processing chamber, if some amount of the film is slightly etched away during plasma processing, the thicker film can extend the lifetime of the baseplate. Furthermore, if portions of the film need to be removed to clean the ESC, the thicker film can lengthen the lifetime of the ESC. Thinner spray coats also might be desired for a couple of properties: e.g., for reduced temperature drop across the coat (i.e., to enable a colder wafer); and for better capacitance matching for improved RF performance. Other benefits are contemplated.

An additional benefit of using the MMC material for the baseplate is that improved CTE matching between the baseplate and the ceramic plate can help with delamination of the bonding layer disposed between the baseplate and the ceramic plate and can also prevent cracking of the ceramic plate. For example, in FIG. 1, the bonding layer 116 that is disposed between the baseplate 112 and the ceramic plate 114 serves multiple purposes, which include physically bonding the baseplate 112 and the ceramic plate 114, improving heat conduction between the baseplate 112 and the ceramic plate 114, and maintaining sufficient elasticity for tolerating shearing stresses over a wide temperature range (the shearing stresses arise due to thermal expansion and contraction of the baseplate 112 and the ceramic plate 114 caused by temperature changes during substrate processing).

To serve these purposes, selecting the composition and thickness of the material for the bonding layer 116 can be challenging when the CTEs of the baseplate 112 and the ceramic plate 114 differ significantly. Specifically, the above thermal and elasticity requirements impose stringent constraints on the selection of the material for the bonding layer 116, which increases cost of ESCs. For example, the material for the bonding layer 116 needs to not only transport heat between the baseplate 112 and the ceramic plate 114 but also maintain elasticity over a wide temperature range to absorb shearing stresses arising due to thermal expansion and contraction of the baseplate 112 and the ceramic plate 114. Failures of the bonding layer 116 such as glass transition (i.e., when the material changes from a rigid glassy material to a soft material) can still occur despite adhering to the stringent constraints, which can cause downtime and further add to the costs.

Using the MMC material for the baseplate 112 with CTE closely matching the CTE of the ceramic plate 114 significantly alleviates the above mentioned constraints on the material used for the bonding layer 116. The baseplate 112 is similar to the baseplate 400 shown in FIGS. 4 and 5 and can be coated with the ceramic coating 404 as shown in FIGS. 4 and 5. Further, the ceramic coating 404 and the ceramic plate 114 may include the same material. Therefore, the CTE of the baseplate 112 matches the CTE of the ceramic plate 114 to the same extent as the CTE of the baseplate 400 matches the CTE of the ceramic coating ceramic coating 404 on the baseplate 400.

Due to the CTE matching between the baseplate 112 and the ceramic plate 114, the material for the bonding layer 116 can be selected from a wide variety of materials with varying thermal and mechanical properties. The thickness of the bonding layer 116 can be relaxed. A bond between the baseplate 112 and the ceramic plate 114 with an unfavorable glass transition of the bonding layer 116 may still be applicable (i.e., may not necessarily cause delamination) due to the improved CTE matching. The bonding layer 116 does not delaminate over a relatively wide temperature range. The bonding layer 116 absorbs the shearing stresses over a relatively wide temperature range for a relatively long time period (e.g., the lifetime of the ESC). Using the MMC material for the baseplate 112 with CTE closely matching the CTE of the ceramic plate 114 can also reduce the risk of cracking of the ceramic plate 114. As a result, the cost of the ESC is reduced, and the life and the reliability of the ESC are enhanced.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

1. A baseplate of a substrate support assembly for supporting a semiconductor substrate in a processing chamber, the baseplate comprising:
a first component made of a first material including a metal and a nonmetal, the first material having a first coefficient of thermal expansion; and
a layer coating the first component and made of a second material, the second material having a second coefficient of thermal expansion;
wherein the first and second coefficients of thermal expansion are different; and
wherein a thickness of the layer of the second material is between 30 μm and 2 mm.

2. The baseplate of claim 1 wherein the first and second coefficients of thermal expansion are within a predetermined range.

3. The baseplate of claim 1 wherein the first coefficient of thermal expansion is greater than the second coefficient of thermal expansion.

4. The baseplate of claim 1 wherein the first coefficient of thermal expansion is less than a coefficient of thermal expansion of the metal.

5. The baseplate of claim 2 wherein:
the predetermined range is between first and second values, the second value being greater than the first value;
the first coefficient of thermal expansion is closer to the second value than the first value; and
the second coefficient of thermal expansion is closer to the first value than the second value.

6. The baseplate of claim 2 wherein the predetermined range is between 6 and 12.

7. (canceled)

8. The baseplate of claim 1 wherein:
the first coefficient of thermal expansion is about 11; and
the second coefficient of thermal expansion is about 8.

9. The baseplate of claim 1 wherein:
the metal is aluminum; and
the nonmetal is silicon carbide.

10. The baseplate of claim 1 wherein the second material is a ceramic material.

11. The baseplate of claim 1 wherein the second material is alumina or yittria.

12. The baseplate of claim 1 further comprising:
a second layer made of a third material disposed on the layer coating the first component; and
a third component made of the second material disposed on the second layer.

13. The baseplate of claim 12 wherein the second layer bonds the third component to the first component.

14. The baseplate of claim 12 wherein the second layer conducts heat between the third component and the first component and absorbs shearing stress over a predetermined temperature range for a predetermined time period.

15. A method for manufacturing a baseplate of a substrate support assembly for supporting a semiconductor substrate in a processing chamber, the method comprising:
manufacturing a first component of the baseplate using a first material including a metal and a nonmetal, the first material having a first coefficient of thermal expansion; and
coating the first component of the baseplate with a layer of a second material having a second coefficient of thermal expansion;
wherein the first and second coefficients of thermal expansion are different; and
wherein a thickness of the layer of the second material is between 30 μm and 2 mm.

16. The method of claim 15 wherein the first and second coefficients of thermal expansion are within a predetermined range.

17. The method of claim 15 wherein the first coefficient of thermal expansion is greater than the second coefficient of thermal expansion.

18. The method of claim 15 wherein the first coefficient of thermal expansion is less than a coefficient of thermal expansion of the metal.

19. The method of claim 15 wherein:
the predetermined range is between first and second values, the second value being greater than the first value;
the first coefficient of thermal expansion is closer to the second value than the first value; and
the second coefficient of thermal expansion is closer to the first value than the second value.

20. The method of claim 16 wherein the predetermined range is between 6 and 12.

21. (canceled)

22. The method of claim 15 wherein:
the first coefficient of thermal expansion is about 11; and
the second coefficient of thermal expansion is about 8.

23. The method of claim 15 further comprising:
selecting aluminum as the metal; and
selecting silicon carbide as the nonmetal.

24. The method of claim 15 further comprising selecting a ceramic material as the second material.

25. The method of claim 15 further comprising selecting alumina or yittria as the second material.
